(19) United States
(12) Patent Application Publication
(10) Pub. No.: US 2014/0225086 A1
(43) Pub. Date: Aug. 14, 2014

(54) ORGANIC LIGHT-EMITTING COMPONENT AND METHOD FOR PRODUCING AN ORGANIC LIGHT-EMITTING COMPONENT

(71) Applicants: Thomas Dobbertin, Regensburg (DE); Erwin Lang, Regensburg (DE); Thilo Reusch, Regensburg (DE); Daniel Steffen Setz, Boeblingen (DE)

(72) Inventors: Thomas Dobbertin, Regensburg (DE); Erwin Lang, Regensburg (DE); Thilo Reusch, Regensburg (DE); Daniel Steffen Setz, Boeblingen (DE)

(73) Assignee: OSRAM OPTO SEMICONDUCTORS GMBH, Regensburg (DE)

(21) Appl. No.: 14/131,685

(22) PCT Filed: Jun. 20, 2012
(86) PCT No.: PCT/EP2012/061794

§ 371 Date: Mar. 4, 2014

(30) Foreign Application Priority Data
Jul. 12, 2011 (DE) 10 2011 079 004.7

(51) Int. Cl. H01L 51/52; H01L 51/56

(52) U.S. Cl. CPC H01L 51/5268; H01L 51/56; H01L 51/5271; H01L 2251/53; H01L 2251/56
USPC 257/40; 438/29

(57) ABSTRACT

An organic light-emitting component, may include: a first electrode; an organic light-generating layer structure on or above the first electrode; a second translucent electrode on or above the organic light-generating layer structure; an optically translucent layer structure on or above the second electrode; and a mirror layer structure on or above the optically translucent layer structure, wherein the mirror layer structure has a light-scattering structure on that side of the mirror layer structure which lies toward the optically translucent layer structure.

### RELATED APPLICATIONS

The present application is a national stage entry according to 35 U.S.C. §371 of PCT application No.: PCT/EP2012/061794 filed on Jun. 20, 2012, which claims priority from German application No. 10 2011 079 004.7 filed on Jul. 12, 2011, and is incorporated herein by reference in its entirety.

### TECHNICAL FIELD

Various embodiments relate to organic light-emitting components and methods for producing an organic light-emitting component.

### BACKGROUND

In an organic light-emitting component such as an organic light-emitting diode, for example, the light generated by said organic light-emitting diode is partly coupled out directly from the organic light-emitting diode. The rest of the light is distributed into various loss channels, as is illustrated in an illustration of a conventional organic light-emitting diode 100 in FIG. 1. FIG. 1 shows an organic light-emitting diode 100 including a glass substrate 102 and a translucent first electrode layer 104 composed of indium tin oxide (ITO) and arranged on said glass substrate. Arranged on the first electrode layer 104 is a first organic layer 106, on which an emitter layer 108 is arranged. A second organic layer 110 is arranged on the emitter layer 108. Illustratively, a light-generating organic layer stack can be provided including at least one emitter layer and additional transport layers, injection layers and optionally other organic functional layers. Furthermore, a second electrode layer 112 composed of a metal is arranged on the second organic layer 110. An electric current supply 114 is coupled to the first electrode layer 104 and to the second electrode layer 112 such that an electric current for generating light is passed through the layer structure arranged between the electrode layers 104, 112. A first arrow 116 symbolizes a loss of generated photons at plasmons in the second electrode layer 112. A further loss channel can be seen in absorption losses in the light emission path (symbolized by means of a second arrow 118). On account of total reflection at the interface between the glass substrate 102 and air (symbolized by means of a third arrow 122), part of the light remains guided in the between substrate underside and second electrode 112 and is not emitted. Analogously, part of the generated light is reflected (symbolized by means of a fourth arrow 124) at the interface between the first electrode layer 104 and the glass substrate 102 and is guided between said interface and the second electrode 112. That portion of the generated light which is coupled out from the glass substrate 102 is symbolized by means of a fifth arrow 120 in FIG. 1. Illustratively, therefore, for example the following loss channels are present: light loss in the glass substrate 102, light loss in the organic layers and the first translucent electrode 106, 110 and surface plasmons generated at the metallic cathode (second electrode layer 112). These light portions cannot readily be coupled out from the organic light-emitting diode 100.

For coupling out substrate modes, so-called coupling-out films are conventionally applied on the underside of the substrate (on the side facing away from the organic light-generating layers) of an organic light-emitting diode, and can couple the light out from the substrate by means of optical scattering or by means of microlenses. However, this leads to a loss of the high-grade glass surface of the organic light-emitting diode. This also leads to an additional process step in the context of the production of the organic light-emitting diode.

It is furthermore known to structure or roughen the lower surface of the substrate directly. However, such a method considerably influences the appearance of the organic light-emitting diode. This is because a milky surface of the substrate arises as a result.

It is furthermore known to apply scattering layers to the underside of the substrate. This, too, considerably influences the appearance of the organic light-emitting diode. This is because a milky surface of the substrate arises as a result. Furthermore, this leads to an additional process step in the context of the production of the organic light-emitting diode.

For coupling out the light in the organic layers of the organic light-emitting diode, various approaches currently exist, but as yet none of these approaches has matured to product readiness.

These approaches are, inter alia:
Introducing periodic structures into the active layers of the organic light-emitting diode (photonic crystals). However, these have a very great dependence on wavelength since the photonic crystals can only couple out specific wavelengths.
Using a high refractive index substrate for directly coupling the light of the organic layers into the substrate. This approach is very cost-intensive on account of the high costs for a high refractive index substrate, and even a high refractive index substrate relies on further coupling-out aids in the form of microlenses, scattering films (each having a high refractive index) or surface structurings.

Furthermore, in the case of an organic light-emitting diode it is known from M. Horii et al., “White Multi-Photon Emission OLED without optical interference”, Proc. Int. Disp. Workshops—vol. 11, pages 1293 to 1296 (2004) to provide a semitransparent cathode and a mirror applied at the rear side (also designated as remote cavity). It is known that such an approach can result in an improvement in the viewing angle dependence of the color angle.

### SUMMARY

Various embodiments provide an organic light-emitting component. The organic light-emitting component may include a first electrode; an organic light-generating layer structure on or above the first electrode; a second translucent electrode on or above the organic light-generating layer structure; an optically translucent layer structure on or above the second electrode; and a mirror layer structure on or above the optically translucent layer, wherein the mirror layer structure has a light-scattering structure on that side of the mirror layer structure which lies toward the optically translucent layer structure. In various embodiments, the optically translucent Layer structure and the mirror layer structure having the light-scattering structure together with the second translucent electrode form a diffuse cavity. The application of the diffuse cavity is effected for example after the application of the electrodes and light-generating layers on the substrate. In various embodiments, a diffuser cavity having light-scattering properties is thus applied.

Various embodiments provide an organic light-emitting component. The organic light-emitting component may include a mirror layer structure; an optically translucent layer structure on or above the mirror layer structure; a first translucent electrode on or above the optically translucent layer structure; an organic light-generating layer structure on or above the first electrode; and a second (for example translucent for example in the case of a top emitter or specularly reflective for example in the case of a bottom emitter) electrode on or above the organic light-generating layer structure. The mirror layer structure has a light-scattering structure on that side of the mirror layer structure which lies toward the optically translucent layer structure. In various exemplary embodiments, the optically translucent layer structure and the mirror layer structure having the light-scattering structure together with the second translucent electrode form a diffuse cavity. In various embodiments, the diffuse cavity is used as a substrate for the application of the translucent electrodes and of the organic light-generating layers.

In various embodiments, illustratively a diffuse cavity is provided as the substrate.

In various embodiments, by comparison with a conventional organic light-emitting component, in the context of the production thereof, it is possible to save a process step whilst at the same time improving the performance of the organic light-emitting component, for example an organic light-emitting diode. In the case of a conventional organic light-emitting diode, a cover glass is adhesively bonded onto the cathode, which is usually non-translucent. In accordance with various embodiments, said cover glass can be replaced by the diffuse cavity (illustratively for example by a structured mirror) and, consequently, no further process step has to be introduced in the entire process sequence for producing the organic light-emitting component.

In various embodiments, the term “translucent” or “translucent layer” can be understood to mean that a layer is transmissive to light, for example to the light generated by the organic light-emitting component, for example in one or more wavelength ranges, for example to light in a wavelength range of visible light (for example at least in a partial range of the wavelength range of from 380 nm to 780 nm). By way of example, in various exemplary embodiments, the term “translucent layer” should be understood to mean that substantially the entire quantity of light coupled into a structure (for example a layer) is also coupled out from the structure (for example layer), wherein part of the light can be scattered in this case.

In various embodiments, the term “transparent” or “transparent layer” can be understood to mean that a layer is transmissive to light (for example at least in a partial range of the wavelength range of from 380 nm to 780 nm), wherein light coupled into a structure (for example a layer) is also coupled out from the structure (for example layer) substantially without scattering or light conversion. Consequently, “transparent” should be regarded as a special case of “translucent”.

For the case where, for example, a light-emitting monochromatic or emission spectrum-limited electronic component is intended to be provided, it suffices for the optically translucent layer structure to be translucent to radiation at least in a partial range of the wavelength range of the desired monochromatic light or for the limited emission spectrum.

In one configuration, the second electrode can be designed in such a way that the optically translucent layer structure is optically coupled to the organic light-generating layer structure.

In one configuration, the optically translucent layer structure can have a layer thickness of at least 1 μm.

In another configuration, the light-scattering structure can have a light-scattering surface structure.

In another configuration, the refractive index of the optically translucent layer structure can be substantially adapted to the refractive index of the organic light-generating layer structure. The performance of the organic light-emitting component is improved further in this way.

In another configuration, the light-scattering structure can be designed in such a way that the scattered light proportion is greater than or equal to, to put it another way has an optical haze of, 20%.

In another configuration, the light-scattering structure may include metal having a roughened metal surface.

In another configuration, the light-scattering structure can have one or a plurality of microlenses.

In another configuration, the mirror layer structure can have a metal mirror structure; wherein the one or a plurality of the plurality of microlenses is or are arranged on or above the metal mirror structure.

In another configuration, the mirror layer structure can have a dielectric mirror structure having scattering centers.

In another configuration, the light-scattering structure can have one or a plurality of periodic structures.

In another configuration, the diffuser cavity can have a lateral thermal conductance of at least 1*10⁻³ W/K. In various exemplary embodiments, a lateral thermal conductance of a layer is understood to mean the product of specific thermal conductivity of the layer material and layer thickness. If the mirror layer structure consists of a plurality of layers, then in various exemplary embodiments the lateral thermal conductance is the sum of the individual lateral thermal conductances.

In another configuration, the optically translucent layer structure can include adhesive material, wherein the adhesive material can include light-scattering particles.

In further configurations, between translucent electrode and diffuse cavity it is possible to insert additional layers for electrical insulation and for encapsulation, for example by means of one or a plurality of “barrier thin-film layer(s)” or one or a plurality of “barrier thin film(s)”.

In the context of this application, a “barrier thin-film layer” or a “barrier thin film” can be understood to mean, for example, a layer or a layer structure which is suitable for forming a barrier against chemical impurities or atmospheric substances, in particular against water (moisture) and oxygen. In other words, the barrier thin-film layer is formed in such a way that OLED-damaging substances such as water, oxygen or solvent cannot penetrate through it or at most very small proportions of said substances can penetrate through it.

Suitable configurations of the barrier thin-film layer can be found for example in the patent applications DE 10 2009 014 543 A1, DE 10 2008 031 405 A1, DE 10 2008 048 472 A1 and DE 2008 019 900 A1.

In accordance with one configuration, the barrier thin-film layer can be formed as an individual layer (to put it another way, as a single layer).

In accordance with an alternative configuration, the barrier thin-film layer may include a plurality of partial layers formed one on top of another. In other words, in accordance with one configuration, the barrier thin-film layer can be formed as a layer stack.

The barrier thin-film layer or one or a plurality of partial layers of the barrier thin-film layer can be formed for example by means of a suitable deposition method, e.g. by means of an atomic layer deposition (ALD) method in accordance with one configuration, e.g. a plasma enhanced atomic layer deposition (PEALD) method or a plasmaless atomic layer deposition (PLALD) method, or by means of a chemical vapor deposition (CVD) method in accordance with another configuration, e.g. a plasma enhanced chemical vapor deposition (PECVD) method or a plasmaless chemical vapor deposition (PLCVD) method, or alternatively by means of other suitable deposition methods.

By using an atomic layer deposition (ALD) method, it is possible for very thin layers to be deposited. In particular, layers having layer thicknesses in the atomic layer range can be deposited.

In accordance with one configuration, in the case of a barrier thin-film layer having a plurality of partial layers, all the partial layers can be formed by means of an atomic layer deposition method. A layer sequence including only ALD layers can also be designated as a “nanolaminate”.

In accordance with an alternative configuration, in the case of a barrier thin-film layer including a plurality of partial layers, one or a plurality of partial layers of the barrier thin-film layer can be deposited by means of a different deposition method than an atomic layer deposition method, for example by means of a vapor deposition method.

In accordance with one configuration, the barrier thin-film layer can have a layer thickness of approximately 0.1 nm (one atomic layer) to approximately 1000 nm, for example a layer thickness of approximately 10 nm to approximately 100 nm in accordance with one configuration, for example approximately 40 nm in accordance with one configuration.

In accordance with one configuration in which the barrier thin-film layer includes a plurality of partial layers, all the partial layers can have the same layer thickness. In accordance with another configuration, the individual partial layers of the barrier thin-film layer can have different layer thicknesses. In other words, at least one of the partial layers can have a different layer thickness than one or more other partial layers.

In accordance with one configuration, the barrier thin-film layer or the individual partial layers of the barrier thin-film layer can be formed as a translucent or transparent layer. In other words, the barrier thin-film layer (or the individual partial layers of the barrier thin-film layer) may consist of a translucent or transparent material (or a material combination that is translucent or transparent).

In accordance with one configuration, the barrier thin-film layer or (in the case of a layer stack having a plurality of partial layers) one or a plurality of the partial layers of the barrier thin-film layer may include or consist of one of the following materials: aluminum oxide, zinc oxide, zirconium oxide, titanium oxide, hafnium oxide, tantalum oxide, lanthanium oxide, silicon oxide, silicon nitride, silicon oxynitride, indium tin oxide, indium zinc oxide, aluminum-doped zinc oxide, and mixtures and alloys thereof.

Various embodiments provide a method for producing an organic light-emitting component. The method may include forming a first electrode; forming an organic light-generating layer structure on or above the first electrode; forming a second electrode on or above the organic light-generating layer structure; forming an optically translucent layer structure on or above the second electrode; and forming a mirror layer structure on or above the optically translucent layer, wherein the mirror layer structure has a light-scattering structure on that side of the mirror layer structure which lies toward the optically translucent layer structure.

Various embodiments provide a method for producing an organic light-emitting component. The method may include forming a mirror layer structure; forming an optically translucent layer structure on or above the mirror layer structure; forming a first electrode on or above the optically translucent layer structure; forming an organic light-generating layer structure on or above the first electrode; forming a second electrode on or above the organic light-generating layer structure; wherein the mirror layer structure has a light-scattering structure on that side of the mirror layer structure which lies toward the optically translucent layer structure.

In one configuration, the optically translucent layer structure may be formed with a layer thickness of at least 1 μm.

In another configuration, the light-scattering structure may have a light-scattering surface structure.

In another configuration, the light-scattering structure may be designed in such a way that the scattered light proportion is greater than or equal to 20%, to put it another way has an optical haze of greater than or equal to 20%.

In another configuration, the light-scattering structure may include metal having a roughened metal surface.

In another configuration, the light-scattering structure may have one or a plurality of microlenses.

In another configuration, the mirror layer structure may have a metal mirror structure; wherein the one or a plurality of the plurality of microlenses is or are formed on or above the metal mirror structure.

In another configuration, the mirror layer structure may have a dielectric mirror structure having scattering centers.

In another configuration, the light-scattering structure may have one or a plurality of periodic structures.

In another configuration, the light-scattering structure may have a lateral thermal conductance of at least 1*10⁻³ W/K.

In another configuration, the optically translucent layer structure may include adhesives, wherein the adhesives may contain light-scattering particles.

In another configuration, the organic light-emitting component may be designed as an organic light-emitting diode or as a light-emitting organic transistor.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a cross-sectional view of a conventional organic light-emitting diode which illustrates light loss channels;

FIG. 2 shows a cross-sectional view of an organic light-emitting component in accordance with various embodiments;

FIG. 3 shows a cross-sectional view of an organic light-emitting component in accordance with various embodiments;

FIGS. 4A to 4F show an organic light-emitting component in accordance with various embodiments at different points in time during the production of said component;

FIG. 5 shows a flow chart illustrating a method for producing an organic light-emitting component in accordance with various embodiments; and

FIG. 6 shows a flow chart illustrating a method for producing an organic light-emitting component in accordance with various embodiments.

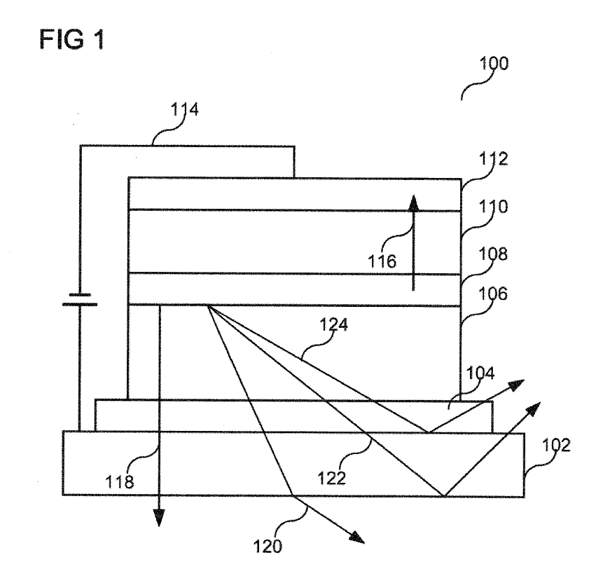

### DETAILED DESCRIPTION

The following detailed description refers to the accompanying drawing that show, by way of illustration, specific details and embodiments in which the disclosure may be practiced.

In the following detailed description, reference is made to the accompanying drawings, which form part of this description and show for illustration purposes specific embodiments in which the disclosure can be implemented. In this regard, direction terminology such as, for instance, “at the top”, “at the bottom”, “at the front”, “at the back”, “front”, “rear”, etc. is used with respect to the orientation of the figure(s) described. Since component parts of embodiments can be positioned in a number of different orientations, the direction terminology serves for illustration and is not restrictive in any way whatsoever. It goes without saying that other embodiments can be used and structural or logical changes can be made, without departing from the scope of protection of the present disclosure. It goes without saying that the features of the various embodiments described herein can be combined with one another, unless specifically indicated otherwise. Therefore, the following detailed description should not be interpreted in a restrictive sense, and the scope of protection of the present disclosure is defined by the appended claims.

In the context of this description, the terms “connected” and “coupled” are used to describe both a direct and an indirect connection and a direct or indirect coupling. In the figures, identical or similar elements are provided with identical reference signs, insofar as this is expedient.

In various embodiments, an organic light-emitting component may be embodied as an organic light-emitting diode (OLED), or as an organic light-emitting transistor (OLET), for example as an organic thin film transistor. In various embodiments, the organic light-emitting component may be part of an integrated circuit. Furthermore, a plurality of organic light-emitting components may be provided, for example in a manner accommodated in a common housing.

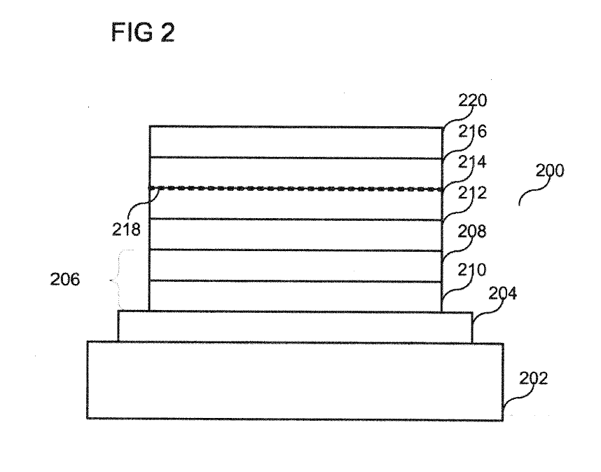

FIG. 2 shows an organic light-emitting diode 200 as an implementation of an organic light-emitting component in accordance with various exemplary embodiments.

The organic light-emitting component 200 in the form of an organic light-emitting diode 200 may have a substrate 202. The substrate 202 may serve for example as a carrier element for electronic elements or layers, for example organic light-emitting elements. By way of example, the substrate 202 can comprise or be formed from glass, quartz, and/or a semiconductor material or any other suitable material. Furthermore, the substrate 202 may include or be formed from a plastic film or a laminate comprising one or comprising a plurality of plastic films. The plastic may include or be formed from one or more polyolefins (for example high or low density polyethylene (PE) or polypropylene (PP)). Furthermore, the plastic may include or be formed from polyvinyl chloride (PVC), polystyrene (PS), polyester and/or polycarbonate (PC), polyethylene terephthalate (PET), polyether sulfone (PES) and/or polyethylene naphthalate (PEN). Furthermore, the substrate 202 may include for example a metal film, for example an aluminum film, a high-grade steel film, a copper film or a combination or a layer stack thereon. The substrate 202 may include one or more of the materials mentioned above. The substrate 202 can be embodied as translucent for example transparent, partly translucent, for example partly transparent, or else opaque.

In various embodiments, the organic light-emitting diode may be designed as a so-called top emitter and/or as a so-called bottom emitter. In various embodiments, a top emitter can be understood to be an organic light-emitting diode in which the light is emitted from the organic light-emitting diode through the side or cover layer situated opposite the substrate, for example through the second electrode. In various embodiments, a bottom emitter can be understood to be an organic light-emitting diode in which the light is emitted from the organic light-emitting diode toward the bottom, for example through the substrate and the first electrode.

The first electrode 204 (also designated hereinafter as bottom electrode 204) may be formed from an electrically conductive material, such as, for example, a metal or a transparent conductive oxide (TCO) or a layer stack including a plurality of layers of the same or different metal or metals and/or the same or different TCOs. Transparent conductive oxides are transparent conductive materials, for example metal oxides, such as, for example, zinc oxide, tin oxide, cadmium oxide, titanium oxide, indium oxide, or indium tin oxide (ITO). Alongside binary metal-oxygen compounds, such as, for example, ZnO, SnO₂, or In₂O₃, ternary metal-oxygen compounds, such as, for example, AIZnO, Zn₂SnO₄, CdSnO₃, ZnSnO₃, MgIn₂O₄, GaInO₃, Zn₂In₂O₅ or In₄Sn₃O₁₂, or mixtures of different transparent conductive oxides also belong to the group of TCOs. Furthermore, the TCOs do not necessarily correspond to a stoichiometric composition and can furthermore be p-doped or n-doped.

In various embodiments, the first electrode 204 may include a metal; for example Ag, Pt, Au, Mg, Al, Ba, In, Ag, Au, Mg, Ca, Sm or Li, and compounds, combinations or alloys of these materials.

In various embodiments, the first translucent electrode 204 may be formed by a layer stack of a combination of a layer of a metal on a layer of a TCO, or vice versa. One example is a silver layer applied on an indium tin oxide layer (ITO) (Ag on ITO) or ITO-Ag-ITO multilayers.

In various embodiments, the first electrode may provide one or a plurality of the following materials as an alternative or in addition to the above-mentioned materials: networks composed of metallic nanowires and nanoparticles, for example composed of Ag; networks composed of carbon nanotubes; graphene particles and graphene layers; networks composed of semiconducting nanowires.

Furthermore, said electrodes may include conductive polymers or transition metal oxides or transparent conductive oxides.

For the case where the light-emitting component 200 emits light through the substrate, the first electrode 204 and the substrate 202 may be formed as translucent or transparent. In this case, for the case where the first electrode 204 is formed from a metal, the first electrode 204 may have for example a layer thickness of less than or equal to approximately 25 nm, for example a layer thickness of less than or equal to approximately 20 nm, for example a layer thickness of less than or equal to approximately 18 nm. Furthermore, the first electrode 204 may have for example a layer thickness of greater than or equal to approximately 10 nm, for example a layer thickness of greater than or equal to approximately 15 nm. In various embodiments, the first electrode 204 can have a layer thickness in a range of approximately 10 nm to approximately 25 nm, for example a layer thickness in a range of approximately 10 nm to approximately 18 nm, for example a layer thickness in a range of approximately 15 nm to approximately 18 nm.

Furthermore, for the case of a translucent or transparent first electrode 204 and for the case where the first electrode 204 is formed from a transparent conductive oxide (TCO), the first electrode 204 can have for example a layer thickness in a range of approximately 50 nm to approximately 500 nm, for example a layer thickness in a range of approximately 75 nm to approximately 250 nm, for example a layer thickness in a range of approximately 100 nm to approximately 150 nm.

Furthermore, for the case of a translucent or transparent first electrode 204 and for the case where the first electrode 204 is formed from, for example, a network composed of metallic nanowires, for example composed of Ag, which can be combined with conductive polymers, a network composed of carbon nanotubes which can be combined with conductive polymers, or from graphene layers and composites, the first electrode 204 can have for example a layer thickness in a range of approximately 1 nm to approximately 500 nm, for example a layer thickness in a range of approximately 10 nm to approximately 400 nm, for example a layer thickness in a range of approximately 40 nm to approximately 250 nm.

For the case where the light-emitting component 200 emits light exclusively toward the top, the first electrode 204 may also be designed as opaque or reflective. For the case where the first electrode 204 is formed as reflective and from metal, the first electrode 204 can have a layer thickness of greater than or equal to approximately 40 nm, for example a layer thickness of greater than or equal to approximately 50 nm.

The first electrode 204 can be formed as an anode, that is to say as a hole-injecting electrode, or as a cathode, that is to say electron-injecting.

The first electrode 204 may have a first electrical terminal, to which a first electrical potential (provided by an energy store (not illustrated) (for example a current source or a voltage source) may be applied. Alternatively, the first electrical potential may be applied to the substrate 202 and then be fed indirectly to the first electrode 204 via said substrate. The first electrical potential can be, for example, the ground potential or some other predefined reference potential.

Furthermore, the organic light-emitting component 200 may have an organic light-generating layer structure 206, which is applied on or above the first translucent electrode 204.

The organic light-generating layer structure 206 may contain one or a plurality of emitter layers 208, for example including fluorescent and/or phosphorescent emitters, and one or a plurality of hole-conducting layers 210. In various embodiments, electron-conducting layers (not illustrated) may alternatively or additionally be provided.

Examples of emitter materials which can be used in the organic light-emitting component in accordance with various embodiments for the emitter layer(s) 208 include organic or organometallic compounds such as derivatives of polyfluorene, polythiophene and polyphenylene (e.g. 2- or 2,5-substituted poly-p-phenylene vinylene) and metal complexes, for example iridium complexes such as blue phosphorescent FIrPic (bis(3,5-difluoro-2-(2-pyridyl)phenyl-(2-carboxypyridyl)iridium III), green phosphorescent Ir(ppy)₃ (tris(2-phenylpyridine)iridium III), red phosphorescent Ru (dtb-bpy)₃*2(PF₆) (tris[4,4′-di-tert-butyl-(2,2′)-bipyridine]ruthenium (III) complex) and blue fluorescent DPAVBi (4,4-bis[4-(di-p-tolylamino)styryl]biphenyl), green fluorescent TTPA (9,10-bis[N,N-di-(p-tolyl)amino]anthracene) and red fluorescent DCM2 (4-dicyanomethylene)-2-methyl-6-julolidyl-9-enyl-4H-pyran) as non-polymeric emitters. Such non-polymeric emitters can be deposited by means of thermal evaporation, for example. Furthermore, it is possible to use polymer emitters, which can be deposited, in particular, by means of wet-chemical methods such as spin coating, for example.

The emitter materials can be embedded in a matrix material in a suitable manner.

It should be pointed out that other suitable emitter materials are likewise provided in other embodiments.

The emitter materials of the emitter layer(s) 208 of the organic light-emitting component 200 can be selected for example such that the organic light-emitting component 200 emits white light. The emitter layer(s) 208 may include a plurality of emitter materials that emit in different colors (for example blue and yellow or blue, green and red); alternatively, the emitter layer(s) 208 may also be constructed from a plurality of partial layers, such as a blue fluorescent emitter layer 208 or blue phosphorescent emitter layer 208, a green phosphorescent emitter layer 208 and a red phosphorescent emitter layer 208. By mixing the different colors, the emission of light having a white color impression can result. Alternatively, provision can also be made for arranging a converter material in the beam path of the primary emission generated by said layers, which converter material at least partly absorbs the primary radiation and emits a secondary radiation having a different wavelength, such that a white color impression results from a (not yet white) primary radiation by virtue of the combination of primary radiation and secondary radiation.

The organic light-generating layer structure 206 may generally include one or a plurality of light-generating layers. The one or the plurality of light-generating layers may include organic polymers, organic oligomers, organic monomers, organic small, non-polymer molecules (“small molecules”) or a combination of these materials. By way of example, the organic light-generating layer structure 206 may include one or a plurality of light-generating layers embodied as a hole transport layer 210, so as to enable for example in the case of an OLED an effective hole injection into an electroluminescent layer or an electroluminescent region. Alternatively, in various embodiments, the organic electroluminescent layer structure may include one or a plurality of functional layers embodied as an electron transport layer 206, so as to enable for example in the case of an OLED an effective electron injection into an electroluminescent layer or an electroluminescent region. By way of example, tertiary amines, carbazo derivatives, conductive polyaniline or polyethylene dioxythiophene can be used as material for the hole transport layer 210. In various embodiments, the one or the plurality of light-generating layers may be embodied as an electroluminescent layer.

In various embodiments, the hole transport layer 210 can be applied, for example deposited, on or above the first electrode 204, and the emitter layer 208 can be applied, for example deposited, on or above the hole transport layer 210.

In various embodiments, the organic light-generating layer structure 206 (that is to say for example the sum of the thicknesses of hole transport layer(s) 210 and emitter layer(s) 208) may have a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various exemplary embodiments, the organic light-generating layer structure 206 can have for example a stack of a plurality of organic light-emitting diodes (OLEDs) arranged directly one above another, wherein each OLED can have for example a layer thickness of a maximum of approximately 1.5 μm, for example a layer thickness of a maximum of approximately 1.2 μm, for example a layer thickness of a maximum of approximately 1 μm, for example a layer thickness of a maximum of approximately 800 nm, for example a layer thickness of a maximum of approximately 500 nm, for example a layer thickness of a maximum of approximately 400 nm, for example a layer thickness of a maximum of approximately 300 nm. In various embodiments, the organic light-generating layer structure 206 can have for example a stack of three or four OLEDs arranged directly one above another, in which case for example the organic light-generating layer structure 206 can have a layer thickness of a maximum of approximately 3 μm.

The organic light-emitting component 200 may optionally generally include further organic functional layers, for example arranged on or above the one or the plurality of emitter layers 208, which serve to further improve the functionality and thus the efficiency of the organic light-emitting component 200.

A second translucent electrode 212 (for example in the form of a second electrode layer 212) may be applied on or above the organic light-generating layer structure 206 or, if appropriate, on or above the one or the plurality of further organic functional layers.

In various embodiments, the second translucent electrode 212 can comprise or be formed from the same materials as the first electrode 204, metals being particularly suitable in various exemplary embodiments.

In various embodiments, the second translucent electrode 212 may include for example a metal having a layer thickness of less than or equal to approximately 50 nm, for example a layer thickness of less than or equal to approximately 45 nm, for example a layer thickness of less than or equal to approximately 40 nm, for example a layer thickness of less than or equal to approximately 35 nm, for example a layer thickness of less than or equal to approximately 30 nm, for example a layer thickness of less than or equal to approximately 25 nm, for example a layer thickness of less than or equal to approximately 20 nm, for example a layer thickness of less than or equal to approximately 15 nm, for example a layer thickness of less than or equal to approximately 10 nm.

The second electrode 212 may generally be formed in a similar manner to the first electrode 104, or differently than the latter. In various embodiments, the second electrode 112 can be formed from one or more of the materials and with the respective layer thickness (depending on whether the second electrode is intended to be formed as reflective, translucent or transparent) as described above in connection with the first electrode 104.

In various embodiments, the second electrode 212 (which can also be designated as top contact 212) may be formed as semitransparent or translucent.

The second electrode 212 may be formed as an anode, that is to say as a hole-injecting electrode, or as a cathode, that is to say electron-injecting.

In the case of these layer thicknesses, the additional microcavity, explained in even greater detail below, can be optically coupled to the microcavity (microcavities) formed by the one or the plurality of light-generating layer structures.

In various embodiments, however, the second electrode 212 can have an arbitrarily greater layer thickness, for example a layer thickness of at least 1

The second electrode 212 can have a second electrical terminal, to which a second electrical potential (which is different than the first electrical potential), provided by the energy source, may be applied. The second electrical potential can have for example a value such that the difference with respect to the first electrical potential has a value in a range of approximately 1.5 V to approximately 20 V, for example a value in a range of approximately 2.5 V to approximately 15 V, for example a value in a range of approximately 5 V to approximately 10 V.

An optically translucent layer structure 214 can be provided on or above the second electrode 212. The optically translucent layer structure 214 may optionally include additional light-scattering particles.

The optically translucent layer structure 214 may be formed from an arbitrary material, in principle, for example a dielectric material, for example an organic material, which forms an organic matrix, for example.

In various embodiments, a mirror layer structure 216 is applied on or above the optically translucent layer structure 214. Illustratively, the optically translucent layer structure 214 and the mirror layer structure 216 jointly form a photoluminescent cavity, for example microcavity, optically coupled (that is to say illustratively external) to the electroluminescent microcavity of the light-emitting component 200, for example the OLED, having one optically active medium or a plurality of optically active media.

In various embodiments, the optically translucent layer structure 214 is transparent or translucent to radiation at least in a partial range of the wavelength range of 380 nm to 780 nm.

For this purpose for example in this embodiment the optically translucent layer structure 214 of the “external” diffuser cavity is brought into contact with the (translucent or semitransparent) second electrode 212 of the OLED microcavity. The “external” cavity does not participate or participates only insignificantly in the current transport through the organic light-emitting component; to put it another way, no or only a negligibly small electric current flows through the “external” diffuser cavity and thus through the optically translucent layer structure 214 and the mirror layer structure 216.

As already set out above, the “external” diffuser cavity, and in this case in particular the optically translucent layer structure 214, in various embodiments, can be “filled” with a suitable organic matrix or be formed by such. The “external” diffuser cavity can have two mirrors or mirror layer structures 216, at least one of which is optically translucent or semitransparent. The optically translucent or semitransparent mirror (or the optically translucent or semitransparent mirror layer structure) can be identical to the optically translucent or semitransparent second electrode 212 of the OLED microcavity (these exemplary embodiments are illustrated in the figures; in alternative embodiments, however, an additionally optically translucent or semitransparent mirror layer structure may also be provided between the second electrode 212 and the optically translucent layer structure 214).

In various embodiments, low molecular weight organic compounds (“small molecules”) may be provided as material for the organic matrix, and may be applied for example by means of vapor deposition in vacuo, such as alpha-NPD or 1-TNATA, for example. In alternative embodiments, the organic matrix can be formed from or consist of polymeric materials which for example form an optically translucent polymeric matrix (epoxides, polymethyl methacryalte, PMMA, EVA, polyester, polyurethanes, or the like) and can be applied by means of a wet-chemical method (for example spin coating or printing method). In various embodiments, for example any organic material such as can also be used in the organic light-generating layer structure 206 can be used for the organic matrix. Furthermore, in alternative embodiments, the optically translucent layer structure 214 may include or be formed by an inorganic semiconductor material for example SiN, SiO₂, GaN, etc., which for example by means of a low-temperature deposition method (for example from the gas phase) (i.e. for example at a temperature of less than or equal to approximately 100° C.). In various embodiments, the refractive indices of the OLED functional layers 206, 208, 210 and of the optically translucent layer structure 214 can be adapted to one another as much as possible, wherein the optically translucent layer structure 214 may also include high refractive index polymers, for example polyamides having a refractive index of up to n=1.7, or polyurethane having a refractive index of up to n=1.74.

In various embodiments, additives can be provided in the polymers. Therefore, illustratively, a high refractive index polymer matrix may be achieved by mixing suitable additives into a polymeric matrix having a normal refractive index. Suitable additives are, for example, titanium oxide or zirconium oxide nanoparticles or compounds comprising titanium oxide or zirconium oxide.

In various embodiments, between the second translucent electrode 212 and the optically translucent layer structure 216 an electrically insulating layer can also be applied, for example SiN, for example having a layer thickness in a range of approximately 30 nm to approximately 1.5 μm, for example having a layer thickness in a range of approximately 200 nm to approximately 1 μm, in order to protect electrically unstable materials, for example during a wet-chemical process.

In various embodiments, a barrier thin-film layer/thin-film encapsulation may optionally also be formed.

In the context of this application, a “barrier thin-film layer” or a “barrier thin film” can be understood to mean, for example, a layer or a layer structure which is suitable for forming a barrier against chemical impurities or atmospheric substances, in particular against water (moisture) and oxygen. In other words, the barrier thin-film layer is formed in such a way that OLED-damaging substances such as water, oxygen or solvent cannot penetrate through it or at most very small proportions of said substances can penetrate through it. Suitable configurations of the barrier thin-film layer can be found for example in the patent applications DE 10 2009 014 543, DE 10 2008 031 405, DE 10 2008 048 472 and DE 2008 019 900.

In accordance with one configuration, the barrier thin-film layer may be formed as an individual layer (to put it another way, as a single layer). In accordance with an alternative configuration, the barrier thin-film layer can comprise a plurality of partial layers formed one on top of another. In other words, in accordance with one configuration, the barrier thin-film layer can be formed as a layer stack. The barrier thin-film layer or one or a plurality of partial layers of the barrier thin-film layer can be formed for example by means of a suitable deposition method, e.g. by means of an atomic layer deposition (ALD) method in accordance with one configuration, e.g. a plasma enhanced atomic layer deposition (PEALD) method or a plasmaless atomic layer deposition (PLALD) method, or by means of a chemical vapor deposition (CVD) method in accordance with another configuration, e.g. a plasma enhanced chemical vapor deposition (PECVD) method or a plasmaless chemical vapor deposition (PLCVD) method, or alternatively by means of other suitable deposition methods.

By using an atomic layer deposition (ALD) method, it is possible for very thin layers to be deposited. In particular, layers having layer thicknesses in the atomic layer range can be deposited.

In accordance with one configuration, in the case of a barrier thin-film layer having a plurality of partial layers, all the partial layers can be formed by means of an atomic layer deposition method. A layer sequence including only ALD layers may also be designated as a “nanolaminate”.

In accordance with an alternative configuration, in the case of a barrier thin-film layer including a plurality of partial layers, one or a plurality of partial layers of the barrier thin-film layer may be deposited by means of a different deposition method than an atomic layer deposition method, for example by means of a vapor deposition method.

In accordance with one configuration, the barrier thin-film layer may have a layer thickness of approximately 0.1 nm (one atomic layer) to approximately 1000 nm, for example a layer thickness of approximately 10 nm to approximately 100 nm in accordance with one configuration, for example approximately 40 nm in accordance with one configuration.

In accordance with one configuration in which the barrier thin-film layer comprises a plurality of partial layers, all the partial layers can have the same layer thickness. In accordance with another configuration, the individual partial layers of the barrier thin-film layer can have different layer thicknesses. In other words, at least one of the partial layers can have a different layer thickness than one or more other partial layers.

In accordance with one configuration, the barrier thin-film layer or the individual partial layers of the barrier thin-film layer can be formed as a translucent or transparent layer. In other words, the barrier thin-film layer (or the individual partial layers of the barrier thin-film layer) can consist of a translucent or transparent material (or a material combination that is translucent or transparent).

In accordance with one configuration, the barrier thin-film layer or (in the case of a layer stack having a plurality of partial layers) one or a plurality of the partial layers of the barrier thin-film layer may include or consist of one of the following materials: aluminum oxide, zinc oxide, zirconium oxide, titanium oxide, hafnium oxide, tantalum oxide, lanthanium oxide, silicon oxide, silicon nitride, silicon oxynitride, indium tin oxide, indium zinc oxide, aluminum-doped zinc oxide, and mixtures and alloys thereof.

In various embodiments, the optically translucent layer structure 216 may have a layer thickness in a range of approximately 10 nm to approximately 200 μm for example a layer thickness in a range of approximately 100 nm to approximately 100 μm, for example a layer thickness in a range of approximately 500 nm to approximately 50 μm, for example 1 μm to 25 μm.

In various embodiments, the optically translucent layer structure 214 may furthermore include or be formed from adhesives, wherein the adhesives can optionally also contain additional light-scattering particles. In various embodiments, the optically translucent layer structure 214 (for example the layer composed of adhesive) may have a layer thickness of greater than 1 μm, for example a layer thickness of several μm.

In various embodiments, between the second electrode 212 and the optically translucent layer structure 214 an electrically insulating layer can also be applied, for example SiN, for example having a layer thickness in a range of approximately 300 nm to approximately 1.5 μm, for example having a layer thickness in a range of approximately 500 nm to approximately 1 μm, in order to protect electrically unstable materials, for example during a wet-chemical process.

One possible advantage of this arrangement, which in various embodiments also forms the “external” diffuser cavity in the front-end-of-line processes, compared with a cavity applied by means of a back-end-of-line process on the outside of the inherently completed organic light-emitting component, can be seen in the strong optical coupling of the optically translucent layer structure 214 to the plasmons in the OLED bottom contact (for example the first electrode 204) or in the OLED top contact (for example the second electrode 212).

In various embodiments, the mirror layer structure 216 (or, if appropriate, the mirror layer structure that can be provided on or above the second electrode 212 below the optically translucent layer structure 214), for the case of a desired high transmissivity, may include one or a plurality of thin metal films (for example Ag, Mg, Sm, Ca, and multilayers and alloys of these materials). The one or the plurality of metal films may have (in each case) a layer thickness of less than or equal to approximately 50 nm, for example a layer thickness of less than or equal to approximately 45 nm, for example a layer thickness of less than or equal to approximately 40 nm, for example a layer thickness of less than or equal to approximately 35 nm, for example a layer thickness of less than or equal to approximately 30 nm, for example a layer thickness of less than or equal to approximately 25 nm, for example a layer thickness of less than or equal to approximately 20 nm, for example a layer thickness of less than or equal to approximately 15 nm, for example a layer thickness of less than or equal to approximately 10 nm.

For this case it is possible to use all those materials for the mirror layer structure 216 (or, if appropriate, the mirror layer structure that can be provided on or above the second electrode 212 below the optically translucent layer structure 214) such as have been mentioned above for the second electrode 212. In this regard, by way of example, it is also possible to provide doped metal-oxidic compounds, such as ITO, IZO or AZO, which can be deposited by means of a low-damage deposition technology such as by means of “facial target sputtering”, for example. It should be noted that the layer thicknesses may be chosen differently when doped metal-oxidic compounds are used.

In various embodiments, the mirror layer structure 216 (or, if appropriate, the mirror layer structure that can be provided on or above the second translucent electrode 212 below the optically translucent layer structure 214), may be reflective or translucent or transparent or semitransparent, depending on whether the organic light-emitting diode 200 is formed as a top emitter and/or as a bottom emitter. The materials can be selected from the materials such as have been mentioned above for the first electrode. The layer thicknesses, too, depending on the desired embodiment of the organic light-emitting diode 200, can be chosen in the ranges such as have been described above for the first electrode. Alternatively or additionally, the mirror layer structure 216 (or, if appropriate, the mirror layer structure that can be provided on or above the second translucent electrode 212 below the optically translucent layer structure 214) can have one or a plurality of dielectric mirrors.

The mirror layer structure 216 can be formed from the same materials as the first electrode 212, wherein the layer thickness can be chosen in such a way that, for the case where the organic light-emitting component 200 is designed as a top emitter, the mirror layer structure 216 may include for example a metal having a layer thickness of less than or equal to approximately 25 nm, for example a layer thickness of less than or equal to approximately 20 nm, for example a layer thickness of less than or equal to approximately 18 nm. In various embodiments, the mirror layer structure 216 may include a metal having a layer thickness in a range of approximately 10 nm to approximately 25 nm, for example a layer thickness in a range of approximately 10 nm to approximately 18 nm, for example a layer thickness in a range of approximately 15 nm to approximately 18 nm.

For the case where the organic light-emitting component 200 is designed as a bottom emitter, then the mirror layer structure 216 may include for example a metal having a layer thickness of greater than or equal to approximately 40 nm, for example a layer thickness of greater than or equal to approximately 50 nm.

The mirror layer structure 216 may have one or a plurality of mirrors. If the mirror layer structure 216 has a plurality of mirrors, then the respective mirrors are separated from one another by means of a respective dielectric layer.

Furthermore, in various embodiments, the mirror layer structure 216 may have one or a plurality of (thin) dielectric mirrors which can form a layer stack. The mirror layer structure 216 having the one or the plurality of (thin) dielectric mirrors can be formed in such a way that a reflection takes place at the interfaces, for example a coherent multiple reflection.

In this way, the transmission or reflection of the mirror layer structure 216 can be set in a very simple manner. The dielectric mirror or mirrors may include one or more of the following materials: for example fluorides (MgF2, CeF3, NaF, LiF, CaF2, Na3, AlF6, AlF3, ThF4), oxides (Al2O3, TiO2, SiO2, ZrO2, HfO2, MgO, Y2O3, La2O3, CeO2, ZnO), sulfides (ZnS, CdS) and compounds such as e.g. ZnSe, ZnSe. In various embodiments, for dielectric thin-film mirrors it is possible to provide a layer sequence including any desired number of thin-film layers (starting with a single one), which are applied with alternating refractive indices (hi-lo-hi-lo). It is thereby possible to achieve very high reflectivities in the visible spectral range.

In various embodiments, the mirror layer structure 216 has a light-scattering structure 218 on that side of the mirror layer structure 216 which lies toward the optically translucent layer structure 214.

The light-scattering structure 218 is thus arranged illustratively at the interface between the mirror layer structure 216 and the optically translucent layer structure 214. The light-scattering structure 218 is designed in such a way that the coupling-out of light from the organic light-emitting component 200 is improved.

The light-scattering structure 218 may have various configurations in various embodiments. In this regard, the light-scattering structure 218 may be formed for example by the mirror layer structure 216 being structured, for example roughened, on the surface facing the optically translucent layer structure 214. Alternatively or additionally, the light-scattering structure 218 can be formed by a roughened metal film (for example an embossed metal mirror having a roughened metal surface) additionally provided. Furthermore alternatively or additionally, the light-scattering structure 218 can be formed by a lens structure (for example formed by microlenses) on which the rest of the mirror structure, for example a metal mirror, is applied. In this case, for example the lens structure and for example the metal mirror can be vapor-deposited onto the exposed surface of the optically translucent layer structure 214.

In various embodiments, the light-scattering structure 218 may thus have a light-scattering surface structure. The light-scattering structure 218 (for example the surface of the mirror layer structure 216) may be designed in such a way that the scattered light proportion is greater than or equal to 20%. To put it another way, it may have an optical haze of at least 20%.

Furthermore, the organic light-emitting diode 200 may also have encapsulation layers, which can be applied for example in the context of a back-end-of-line process, wherein it should be pointed out that in various embodiments the external cavity is formed in the context still of the front-end-of-line process.

The organic light-emitting diode 200 may be formed as a bottom emitter or as a top emitter or as a top and bottom emitter.

Furthermore, a cover layer 220, for example a glass 220, may optionally be applied on or above the mirror layer structure 216.

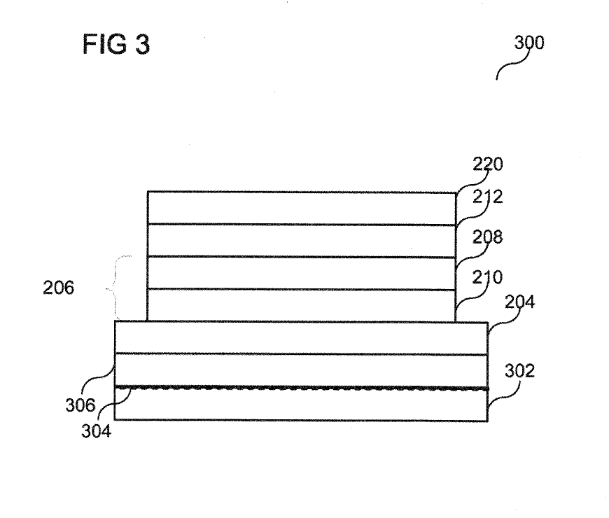

FIG. 3 shows an organic light-emitting diode 300 as an implementation of an organic light-emitting component in accordance with various embodiments.

The organic light-emitting diode 300 in accordance with FIG. 3 is identical in many aspects to the organic light-emitting diode 200 in accordance with FIG. 2, for which reason only the differences between the organic light-emitting diode 300 in accordance with FIG. 3 and the organic light-emitting diode 200 in accordance with FIG. 2 are explained in greater detail below; with regard to the remaining elements of the organic light-emitting diode 300 in accordance with FIG. 3, reference is made to the above explanations concerning the organic light-emitting diode 200 in accordance with FIG. 2.

In contrast to the organic light-emitting diode 200 in accordance with FIG. 2, in the case of the organic light-emitting diode 300 in accordance with FIG. 3, the mirror layer structure 302 having the light-scattering structure 304 and the optically translucent layer structure are not formed on or above the second electrode 212, but rather below the first electrode 204.

In these embodiments, the energy source is connected to the first electrical terminal of the first electrode 204 and to the second electrical terminal of the second electrode 212.

The organic light-emitting diode 300 in accordance with FIG. 3 may be formed as a bottom emitter or as a top emitter or as a top and bottom emitter.

In various embodiments, the mirror layer structure 302 provided with the light-scattering structure 304 serves as a substrate (even if, in various alternative embodiments, a substrate on which the mirror layer structure 302 can be applied can be additionally provided). The mirror layer structure 302 and the light-scattering structure 304 of the mirror layer structure 302 of the organic light-emitting diode 300 in accordance with FIG. 3 can be formed in the same way as the mirror layer structure 216 provided with the light-scattering structure 218 of the organic light-emitting diode 200 in accordance with FIG. 2.

Therefore, illustratively in these embodiments the optically translucent layer structure 306 (which can be formed identically to the optically translucent layer structure 214 in accordance with FIG. 2) is arranged on or above the mirror layer structure 302, wherein the light-scattering structure 304 is arranged at the interface of the mirror layer structure 302 and the optically translucent layer structure 306. Therefore, illustratively the “external cavity” is arranged below the first electrode 212. The first electrode 212 is arranged on or above the optically translucent layer structure 306.

The rest of the layer stack of the organic light-emitting component 300 in accordance with FIG. 3 is similar to that of the organic light-emitting component 200 in accordance with FIG. 2.

To put it another way, the organic light-generating layer structure 206 having for example the one or the plurality of emitter layers 208 and the one or the plurality of hole-conducting layers 210 is arranged on or above the first electrode 204. The second electrode 212 is arranged on or above the organic light-generating layer structure 206 and, if appropriate, the cover layer 220, for example a glass 220, is arranged on or above the second electrode 212.

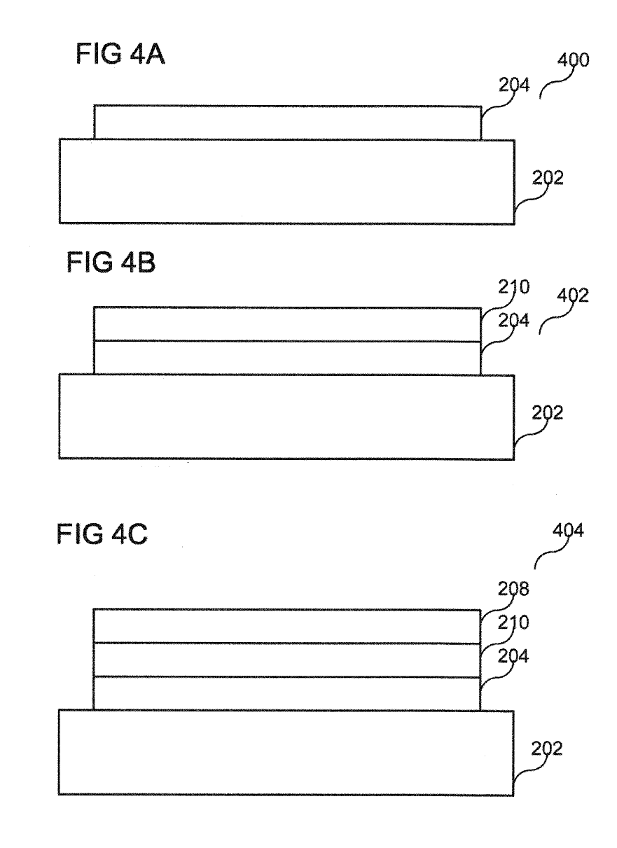

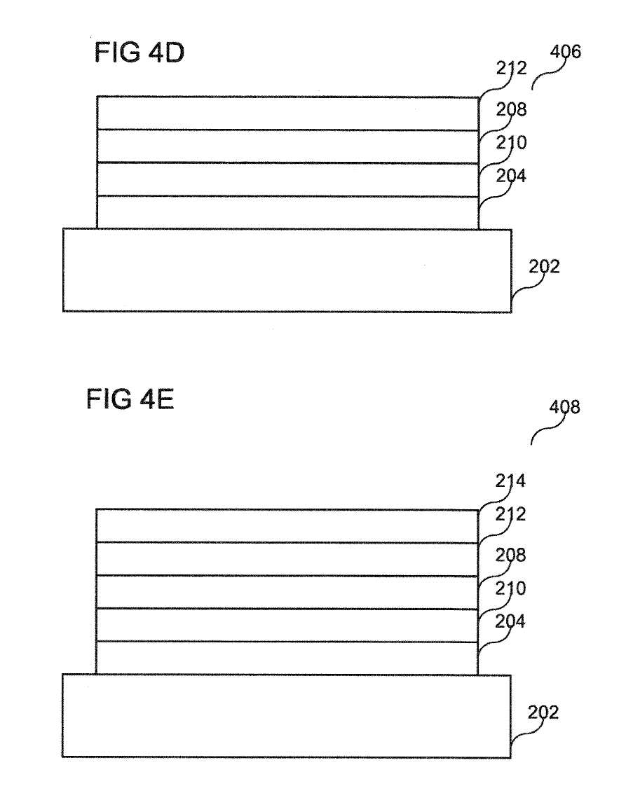

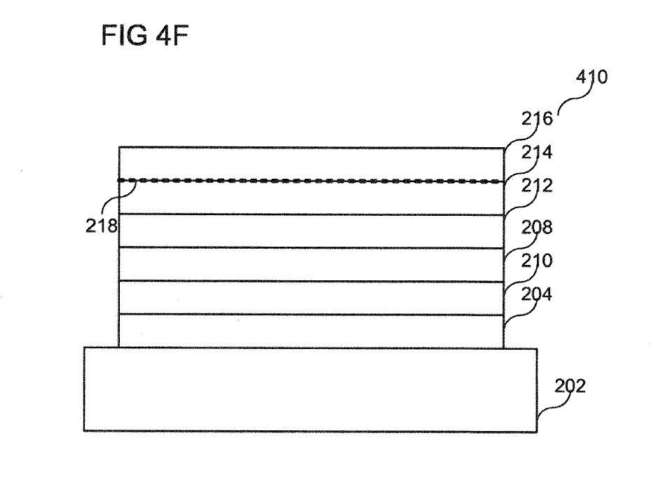

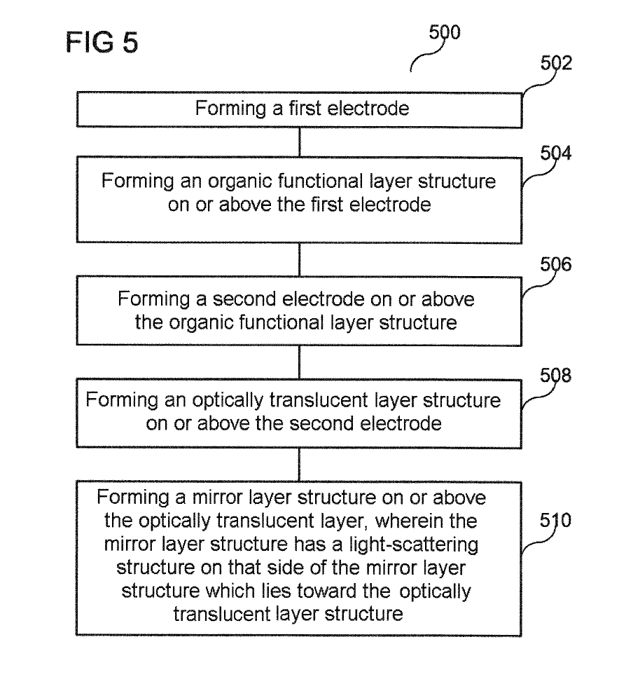

FIG. 4A to FIG. 4F show the organic light-emitting component 200 in accordance with various embodiments at different points in time during the production of said component. The other organic light-emitting component 300 is produced in a corresponding manner.

FIG. 4A shows the organic light-emitting component 100 at a first point in time 400 during the production of said component.

At this point in time, the first electrode 204 is applied to the substrate 202, for example deposited onto said substrate, for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

In various embodiments, a plasma enhanced chemical vapor deposition (PE-CVD) method may be used as CVD method. In this case, a plasma can be generated in a volume above and/or around the element to which the layer to be applied is intended to be applied, wherein at least two gaseous starting compounds are fed to the volume, said compounds being ionized in the plasma and excited to react with one another. The generation of the plasma can make it possible that the temperature to which the surface of the element is to be heated in order to make it possible to produce the dielectric layer, for example, can be reduced in comparison with a plasmaless CVD method. That may be advantageous, for example, if the element, for example the light-emitting electronic component to be formed, would be damaged at a temperature above a maximum temperature. The maximum temperature can be approximately 120° C. for example in the case of a light-emitting electronic component to be formed in accordance with various embodiments, such that the temperature at which the dielectric layer for example is applied can be less than or equal to 120° and for example less than or equal to 80° C.

FIG. 4B shows the organic light-emitting component 200 at a second point in time 402 during the production of said component.

At this point in time, the one or the plurality of hole-conducting layers 210 is or are applied to the first electrode 204, for example deposited onto said first electrode, for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

FIG. 4C shows the organic light-emitting component 200 at a third point in time 404 during the production of said component.

At this point in time, the one or the plurality of emitter layers 208 is or are applied to one or the plurality of hole-conducting layers 210, for example deposited onto said hole-conducting layer(s), for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

FIG. 4D shows the organic light-emitting component 200 at a fourth point in time 406 during the production of said component.

At this point in time, the second electrode 212 is applied to the one or the plurality of further organic functional layers (if present) or to the one or the plurality of emitter layers 208, for example deposited onto said layer(s), for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

FIG. 4E shows the organic light-emitting component 200 at a fifth point in time 408 during the production of said component.

At this point in time, the optically translucent layer structure 214 is applied to the second electrode 212, for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

FIG. 4F shows the organic light-emitting component 200 at a sixth point in time 410 during the production of said component.

At this point in time, the mirror layer structure 216 having the roughened or structured surface (generally having the light-scattering structure 218) oriented toward the optically translucent layer structure 214 is applied to the optically translucent layer structure 214, depending on the type of light-scattering structure 218 for example by means of a CVD method (chemical vapor deposition) or by means of a PVD method (physical vapor deposition, for example sputtering, ion-assisted deposition method or thermal evaporation), alternatively by means of a plating method; a dip coating method; a spin coating method; printing; blade coating; or spraying.

The cover layer 220 is then also optionally applied, whereby the organic light-emitting component 200 in accordance with FIG. 2 is completed.

FIG. 5 shows a flow chart 500 illustrating a method for producing an organic light-emitting component in accordance with various embodiments.

In various embodiments, in 502 a first electrode is formed, for example on or above a substrate. Furthermore, in 504 an organic light-generating layer structure is formed on or above the first electrode, and in 506 a second electrode is formed on or above the organic light-generating layer structure. Furthermore, in 508 an optically translucent layer structure is formed on or above the second electrode. Finally, in various exemplary embodiments, in 510 a mirror layer structure is formed on or above the optically translucent layer, wherein the mirror layer structure has a light-scattering structure on that side of the mirror layer structure which lies toward the optically translucent layer structure.

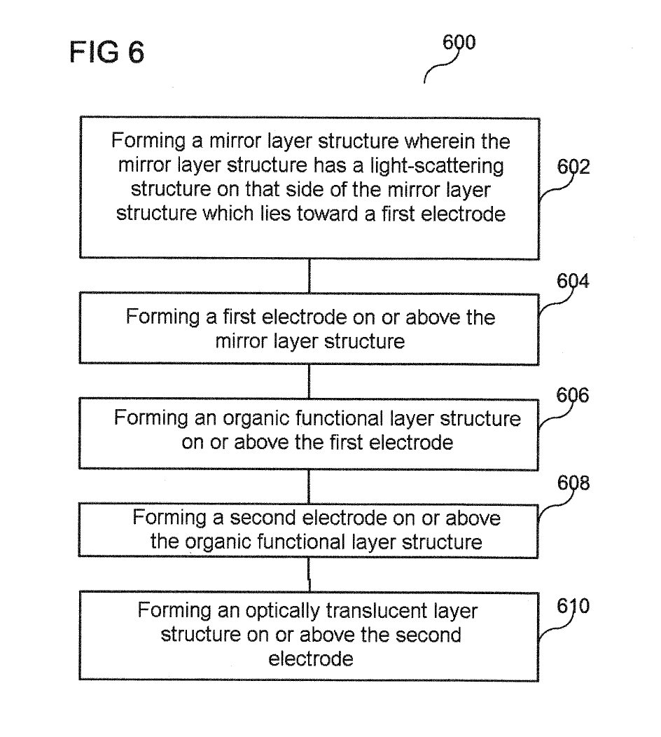

FIG. 6 shows a flow chart 600 illustrating a method for producing an organic light-emitting component in accordance with various embodiments.

In various embodiments, in 602 a mirror layer structure is formed and in 604 a first electrode is formed on or above the mirror layer structure. Furthermore, in 606 an organic light-generating layer structure is formed on or above the first electrode and in 608 a second electrode is formed on or above the organic light-generating layer structure. In 610, an optically translucent layer structure is formed on or above the second electrode. The mirror layer structure has a light-scattering structure on that side of the mirror layer structure which lies toward the first electrode.

In various embodiments, in the design of an organic light-emitting component, for example an organic light-emitting diode, the top contact, for example the second electrode 214, can be fashioned as semitransparent in order that part of the light generated by the organic light-emitting component, for example the organic light-emitting diode, is also coupled out toward the rear side. If a structured mirror (for example a mirror of the MIRO series from Alanod) is applied or provided behind said top contact, the path of the light is altered at said mirror, which improves both the coupling-out of the light and the viewing angle dependence of the emission color.

The structured mirror may, as has been described above, be applied to the for example thin-film-encapsulated translucent top contact by means of an adhesive (as an implementation of an adhesive material). The adhesive material (which can have a layer thickness of a few μm and illustratively forms a component of the “external” cavity, namely the optically translucent layer structure) can additionally comprise light-scattering particles (for example comprising or consisting of Al₂0₃ and/or TiO₂). The light-scattering particles can be coated or uncoated. The light-deflecting effect of the light-scattering structure can additionally be intensified by means of the light-scattering particles. The higher the refractive index for example of the adhesive material, the better this effect (for example up to a refractive index of approximately n=1.8). For the translucent top contact having the highest possible transmissivity, it is possible to use a thin metal film (for example including one of the above-mentioned materials, for example comprising Ag, Mg, Sm, Au, Ca, and comprising a plurality of such layers comprising these materials, which form a layer stack, and/or comprising one or a plurality of alloys of these materials). Moreover, in various embodiments, it is possible to provide doped metal-oxidic compounds such as, for example, ITO, IZO or AZO or combinations of one or a plurality of thin metal layers and doped metal-oxidic compounds (for example an ITO layer and an AG layer) for example in conjunction with low-damage deposition technologies such as facial target sputtering (FTS), for example.

In various embodiments, the mirror, in general for example the mirror layer structure 216, can have the highest possible total reflectivity and can be formed from various materials such as, for example various metals (aluminum, silver, gold, etc.) or alloys thereof (for example Mg:Ag, Ca:Ag, etc.). In various embodiments, the total reflectivity of the mirror or of the mirror layer structure 216 can be increased further by means of one or a plurality of dielectric layers additionally provided.

In various embodiments, the surface structure (which faces toward the optically translucent layer structure 214) of the mirror layer structure 216 or of the light-scattering structure 218 may have a stochastic structuring and can thus have a stochastic character. Alternatively or additionally, the surface structure (which faces toward the optically translucent layer structure 214) of the mirror layer structure 216 or of the light-scattering structure 218 can have one or a plurality of periodic structures. In various embodiments, the roughness of the surface structure (which faces toward the optically translucent layer structure 214) of the mirror layer structure 216 or of the light-scattering structure 218 can be in the micrometers range. Furthermore, in various embodiments, the surface structure (which faces toward the optically translucent layer structure 214) of the mirror layer structure 216 or of the light-scattering structure 218 can have parabolic structures which tend to direct the light toward the front and can thus also influence the emission profile of the organic light-emitting diode, for example.

In various embodiments, the metal mirror can either be deposited on a glass plate or consist completely of metal, for example in the form of one metal strip or a plurality of metal strips or one or a plurality of metal plates). Through the use of one or a plurality of metal strips and/or one or a plurality of metal plates, it is additionally possible to obtain an improvement in the heat distribution on an OLED tile, which can have a positive effect on the operating life.

In various embodiments, provision can furthermore be made for depositing the structure of the organic light-emitting component 200 as illustrated in FIG. 2 in an inverted fashion, whereby the structure of the organic light-emitting component 300 as illustrated in FIG. 32 is formed. In this case, by way of example, the structured mirror is used as substrate and planarized with a layer having the highest possible refractive index. On this foundation it is possible to deposit for example the bottom contact, for example the first electrode 204, formed from the materials mentioned above. The top contact, that is to say for example the second electrode 212, can likewise be formed as semitransparent in this case.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An organic light-emitting component, comprising:
a first electrode;
an organic light-generating layer structure on or above the first electrode;
a second translucent electrode on or above the organic light-generating layer structure;
an optically translucent layer structure on or above the second electrode (212); and
a mirror layer structure on or above the optically translucent layer structure, wherein the mirror layer structure has a light-scattering structure on that side of the mirror layer structure which lies toward the optically translucent layer structure.

2. An organic light-emitting component comprising:
a mirror layer structure;
an optically translucent layer structure on or above the mirror layer structure;
a first translucent electrode on or above the optically translucent layer structure;
an organic light-generating layer structure on or above the first electrode; and
a second electrode on or above the organic light-generating layer structure;
wherein the mirror layer structure has a light-scattering structure on that side of the mirror layer structure which lies toward the optically translucent layer structure.

3. The organic light-emitting component as claimed in claim 1,
wherein the optically translucent layer structure and the mirror layer structure form a diffuser cavity.

4. The organic light-emitting component as claimed in claim 1,
wherein the optically translucent layer structure has a layer thickness of at least 1 μm.

5. The organic light-emitting component as claimed in claim 1,
wherein the light-scattering structure has a light-scattering surface structure.

6. The organic light-emitting component as claimed in claim 1,
wherein the light-scattering structure is designed in such a way that the scattered light proportion is greater than or equal to 20%.

7. The organic light-emitting component as claimed in claim 1,
wherein the light-scattering structure comprises metal having a roughened metal surface.

8. The organic light-emitting component as claimed in claim 1,
wherein the light-scattering structure has one or a plurality of microlenses.

9. The organic light-emitting component as claimed in claim 8,
wherein the mirror layer structure has a metal mirror structure;
wherein the one or a plurality of the plurality of microlenses is or are arranged on or above the metal mirror structure.

10. The organic light-emitting component as claimed in claim 1,
wherein the mirror layer structure has a dielectric mirror structure having scattering centers.

11. The organic light-emitting component as claimed in claim 1,
wherein the light-scattering structure has one or a plurality of periodic structures.

12. The organic light-emitting component as claimed in claim 1,
wherein the light-scattering structure has a lateral thermal conductance of at least 1*10⁻³ W/K.

13. The organic light-emitting component as claimed in claim 1,
wherein the optically translucent layer structure has one adhesive or a plurality of adhesives.

14. The organic light-emitting component as claimed in claim 13,
wherein the one adhesive or the plurality of adhesives comprises or comprise light-scattering particles.

15. A method for producing an organic light-emitting component, the method comprising:
forming a first electrode;
forming an organic light-generating layer structure on or above the first electrode;
forming a second translucent electrode on or above the organic light-generating layer structure;
forming an optically translucent layer structure on or above the second electrode; and
forming a mirror layer structure on or above the optically translucent layer, wherein the mirror layer structure has a light-scattering structure on that side of the mirror layer structure which lies toward the optically translucent layer structure.

16. A method for producing an organic light-emitting component, the method comprising:
forming a mirror layer structure;
forming an optically translucent layer structure on or above the mirror layer structure;
forming a first translucent electrode on or above the optically translucent layer structure;
forming an organic light-generating layer structure on or above the first electrode; and
forming a second electrode on or above the organic light-generating layer structure;
wherein the mirror layer structure has a light-scattering structure on that side of the mirror layer structure which lies toward the optically translucent layer structure.

17. The organic light-emitting component as claimed in claim 2,
wherein the optically translucent layer structure and the mirror layer structure form a diffuser cavity.

18. The organic light-emitting component as claimed in claim 2,
wherein the optically translucent layer structure has a layer thickness of at least 1 μm.

19. The organic light-emitting component as claimed in claim 2,
wherein the light-scattering structure has a light-scattering surface structure.

20. The organic light-emitting component as claimed in claim 2,
wherein the light-scattering structure is designed in such a way that the scattered light proportion is greater than or equal to 20%.

21. The organic light-emitting component as claimed in claim 2,
wherein the light-scattering structure comprises metal having a roughened metal surface.

22. The organic light-emitting component as claimed in claim 2,
wherein the light-scattering structure has one or a plurality of microlenses.

23. The organic light-emitting component as claimed in claim 22,
wherein the mirror layer structure has a metal mirror structure;
wherein the one or a plurality of the plurality of microlenses is or are arranged on or above the metal mirror structure.

24. The organic light-emitting component as claimed in claim 2,
wherein the mirror layer structure has a dielectric mirror structure having scattering centers.

25. The organic light-emitting component as claimed in claim 2,
wherein the light-scattering structure has one or a plurality of periodic structures.

26. The organic light-emitting component as claimed in claim 2,
wherein the light-scattering structure has a lateral thermal conductance of at least 1*10⁻³ W/K.

27. The organic light-emitting component as claimed in claim 2,
wherein the optically translucent layer structure has one adhesive or a plurality of adhesives.

28. The organic light-emitting component as claimed in claim 27,
wherein the one adhesive or the plurality of adhesives comprises or comprise light-scattering particles.
